(19) United States
(12) Patent Application Publication
(10) Pub. No.: US 2009/0134776 A1
(43) Pub. Date: May 28, 2009

(54) ELECTROLUMINESCENCE ELEMENT AND DISPLAY DEVICE

(76) Inventors: Masayuki Ono, Osaka (JP); Shogo Nasu, Hyogo (JP); Toshiyuki Aoyama, Osaka (JP); Masaru Odagiri, Hyogo (JP)

Correspondence Address: MCDERMOTT WILL & EMERY LLP, 600 13TH STREET, NW, WASHINGTON, DC, 20005-3096, US

(21) Appl. No.: 12/065,796

(22) PCT Filed: Sep. 4, 2006
(86) PCT No.: PCT/JP2006/317464

§ 371 Date: Mar. 5, 2008

(30) Foreign Application Priority Data
Sep. 5, 2005 (JP) 2005-256110

(51) Int. Cl. H01L 51/54; H01L 51/50; H01L 51/52

(52) U.S. Cl. 313/503; 313/509; 313/505

(57) ABSTRACT

The electroluminescent element includes a first electrode, a first dielectric layer formed on the first electrode, a second dielectric layer formed opposed to the first dielectric layer, a second electrode formed on the second dielectric layer, a phosphor layer sandwiched between the first dielectric layer and the second dielectric layer, and a photoelectric conversion layer that generates electron-hole pairs by light from the phosphor layer, the photoelectric conversion layer being sandwiched between the first dielectric layer and the second dielectric layer. At least one of the first electrode and the second electrode is transparent or translucent.

### BACKGROUND

1. Field of the Invention

This invention relates to an electroluminescence element and a display device.

2. Description of the Related Art

In recent years, among flat-type display devices, those using electroluminescence elements (hereinafter, referred to simply as EL) have been attracting high expectations. The EL element has features such as a self light-emitting property, a superior visibility, a wide viewing angle and a high responsivity. The EL elements currently under development include inorganic EL elements using an inorganic material as a phosphor material and organic EL elements using an organic material as a phosphor material.

The inorganic EL element uses an inorganic fluorescent material such as zinc sulfide as a phosphor material, and causes electrons accelerated in an electric field as high as 10⁶V/cm to collide with luminescent centers of the fluorescent material to excite the fluorescent material, whereupon light is emitted when they are relaxed. Moreover, the inorganic EL elements are categorized as dispersion-type EL elements having a structure in which fluorescent powder is dispersed in a polymer organic material or the like with electrodes provided above and below the material, and as thin-film EL elements having a structure in which two dielectric layers are formed between a pair of electrodes with a thin-film phosphor layer further sandwiched between the dielectric layers. The dispersion-type EL elements have low brightness and a short lifetime, although they are easily manufactured; therefore, the application thereof have been limited. In contrast, with respect to the thin-film EL elements, those having a double insulation structure proposed by Inokuchi et al. in 1974 have high brightness and a long lifetime, and have been put into practical use such as displays for vehicles. Moreover, inorganic EL elements have been disclosed in which insulating ceramic substrates are used as substrates, and one of the dielectric layers forming the double insulation structure is constituted as a thick-film dielectric material (for example, see Japanese Patent Publication No. H07-44072). These inorganic EL elements make it possible to reduce dielectric breakdown at the time of being driven due to pinholes formed by dusts and the like occurred during the manufacturing process.

Referring to FIG. 4, a description will be made on the double insulation-type EL element as a typical conventional inorganic EL element. The inorganic EL element 40 is formed by a transparent electrode 42, a first dielectric layer 43, a phosphor layer 44, a second dielectric layer 46 and an opposing electrode 47 that are stacked on a transparent substrate 41 in this order. The first dielectric layer 43 and the second dielectric layer 46 have a function for regulating an electric current flowing through the phosphor layer 44, thereby capable of preventing dielectric breakdown in the element 40 and also providing a stable light-emitting property. A display device of a passive-matrix driving system is also known in which transparent electrodes 41 and opposing electrodes 47 are patterned into a stripe so as to be orthogonal to each other, and a voltage is applied to a specific pixel selected on the matrix so that a desired pattern displaying is carried out.

The dielectric material used for the first dielectric layer 43 and the second dielectric layer 46 includes, for example, Y₂O₃, Ta₂O₅, Al₂O₃, Si₃N₄, BaTiO₃ and SrTiO₃, and is formed into a film through methods such as sputtering and vapor deposition.

The inorganic fluorescent material used in the phosphor layer 44 is generally provided by using an insulator crystal as a host crystal with an element forming luminescence centers doped in the host crystal. Since a material that is stable physically and chemically is used as the host crystal, the inorganic EL element is highly reliable, and achieves a lifetime exceeding 30,000 hours or more. However, although the light-emitting brightness is improved by constituting the phosphor layer mainly made from ZnS with a transition metal element and a rare-earth element such as Mn, Cr, Tb, Eu, Tm and Yb doped therein, the average brightness is less than 400 cd/m², which is insufficient for use in display devices such as televisions (see Japanese Patent Publication No. S54-8080).

In the case where an EL element is utilized in a display device such as televisions, the brightness having an average brightness of 400 cd/m² or more and the lifetime of at least about 30,000 hours are required. The conventional inorganic EL element fails to provide sufficient brightness.

The object of the present invention is to provide an EL element capable of solving the problems in the conventional EL element and providing a high brightness and a long lifetime, and a display device using the EL element.

### SUMMARY OF THE INVENTION

An electroluminescent element according to an aspect of the present invention includes:

a first electrode;

a first dielectric layer formed on the first electrode;

a second dielectric layer formed to oppose the first dielectric layer;

a second electrode formed on the second dielectric layer;

a phosphor layer sandwiched between the first dielectric layer and the second dielectric layer; and

a photoelectric conversion layer which generates electron-hole pairs by light from the phosphor layer, wherein the photoelectric conversion layer is sandwiched between the first dielectric layer and the second dielectric layer,

wherein at least one of the first electrode and the second electrode is transparent or translucent.

An electroluminescent element according to another aspect of the present invention includes:

a first electrode that is transparent or translucent;

a first dielectric layer formed on the first electrode;

a phosphor layer formed on the first dielectric layer;

a photoelectric conversion layer formed on the phosphor layer, which generates electron-hole pairs by light from the phosphor layer;

a second dielectric layer formed on the photoelectric conversion layer; and

a second electrode formed on the second dielectric layer.

According to a further aspect of the present invention, the photoelectric conversion layer may mainly include at least one material of an amorphous calcogenide-based material, an amorphous tetrahedral-based material, and a semiconductor material of a compound belonging to any of Groups 12 to 16.

Further, according to a yet further aspect of the present invention, the photoelectric conversion layer may mainly include at least one material of a condensed polycyclic quinone-based material, an azo-based material, an indigo-based material, a phthalocyanine-based material, a naphthalocyanine-based material, a squarylium-based material, an azulenium-based material, a thiapyrilium-based material, and a cyanine-based material.

Further, according to a yet further aspect of the present invention, the phosphor layer may be an inorganic fluorescent thin film.

A display device according to still another aspect of the present invention includes:

a light-emitting element array in which a plurality of the electroluminescent elements are two-dimensionally arranged;

a plurality of x-electrodes extending in parallel with each other in a first direction parallel with a light-emitting surface of the light-emitting element array; and

a plurality of y-electrodes extending in parallel with a second direction that is orthogonal to the first direction and is parallel with the light-emitting surface of the light-emitting element array.

According to the EL element of the present invention, since a photoelectric conversion layer is provided adjacent to a phosphor layer, electron-hole pairs are generated in the photoelectric conversion layer by light emission from a fluorescent material inside the phosphor layer, and, upon application of a voltage to the element, electrons separated by the electric field intensity are made to collide with and excite the fluorescent material inside the phosphor layer. Since the density of electrons contributing to light emission increases in comparison with that of the conventional inorganic EL element, a light-emitting element with high brightness and a display device using the same can be provided.

### BRIEF DESCRIPTION OF THE DRAWINGS

The present invention will become readily understood from the following description of preferred embodiments thereof made with reference to the accompanying drawings, in which like parts are designated by like reference numeral and in which:

FIG. 1 is a cross-sectional view perpendicular to a light-emitting surface of an EL element according to a first embodiment of the present invention;

FIG. 2 is a perspective view showing a display device according to a second embodiment of the present invention;

FIG. 3 is a cross-sectional view perpendicular to a light-emitting surface of an EL element according to a third embodiment of the present invention; and

FIG. 4 is a cross-sectional view perpendicular to a light-emitting surface of a conventional EL element.

### DESCRIPTION OF THE PREFERRED EMBODIMENTS

An EL element according to embodiments of the present invention and a display device using the same will be described below with reference to the attached drawings. In the drawings, substantially the same members are indicated by the same reference numerals.

### First Embodiment

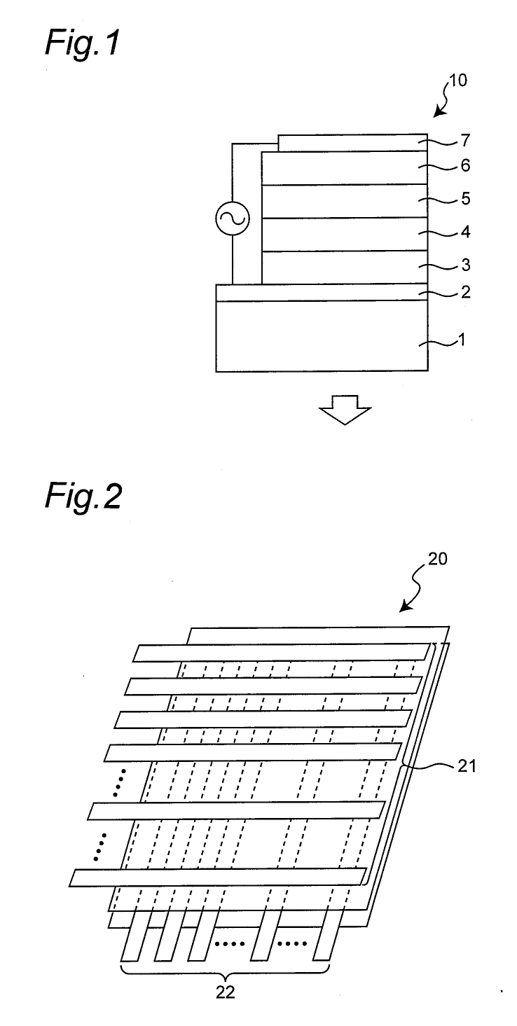

Referring to FIG. 1, an EL element according to the first embodiment of the present invention will be described. FIG. 1 is a cross-sectional view that is perpendicular to the light-emitting surface of an EL element 10. This EL element 10 has a phosphor layer 4 made of an inorganic fluorescent material that is sandwiched by two first and second dielectric layers 3 and 6, and the dielectric layers 3 and 6 are further sandwiched between a transparent electrode 2 and an opposing electrode 7. Moreover, a photoelectric conversion layer 5 is sandwiched between the phosphor layer 4 and the second dielectric layer. The EL element 10 is formed by sequentially stacking the transparent electrode 2, the first dielectric layer 3, the phosphor layer 4, the photoelectric conversion layer 5, the second dielectric layer 6 and the opposing electrode 7 on a transparent substrate 1. Light emission from the inorganic fluorescent material is taken out from the transparent substrate 1. Here, in addition to the above-mentioned structure, a structure for sealing the whole or one portion of the EL element 10 may be further provided. With this arrangement, even when an inorganic fluorescent material having a problem with, e.g. moisture resistance is used, the reliability can be improved and the lifetime of the EL element 10 can be extended. The opposing electrode 7 may have black color. The second dielectric layer 6 may include pigments or the like that exhibits black color. According to the arrangement, external light incident on the EL element 10 from the transparent electrode 2 is prevented from being reflected on the surface of the opposing electrode 7, so that a high external light contrast can be achieved. Moreover, when the opposing electrode 7 is a transparent electrode, light emission can be taken out from the surfaces of the both electrodes.

The respective components of the EL element 10 will be described in detail.

The transparent substrate 1 is explained. Any substrate capable of supporting the layers formed thereon may be used as the transparent substrate 1. Moreover, the substrate is made transparent or translucent so that light emission generated in the phosphor layer 4 can taken out, and is made from a material having a high electric insulating property. With respect to the transparent substrate 1, for example, a glass substrate of, for example, Corning 1737, may be used. In order to prevent alkali ions or the like contained in normal glass from affecting the light-emitting element, non-alkaline glass and soda lime glass whose surface is coated with alumina or the like as an ion barrier layer may also be used. Moreover, a resin film such as polyester may be used. With respect to the resin film, a material that are good in endurance, flexibility, transparency, electric insulation and moisture resistance is preferably used, and a combination of polyethylene terephthalate-based resin or polychlorotrifluoro ethylene-based resin and Nylon 6, and a fluororesin-based material or the like may be used.

Next, the transparent electrode 2 is described. A material having transparency and conductivity may be used as transparent electrode 2. The transparent electrode 2 preferably has a low electric resistance. Particularly preferable examples of the transparent electrode 2 include ITO (indium-tin oxide), InZnO and SnO₂. It is noted that the transparent electrode 2 is not limited in the above-mentioned materials. In order to improve the transparency or reduce the resistivity, ITO is formed into a film by using a film-forming method such as a sputtering method, an electron beam vapor deposition method and an ion plating method. Moreover, after the film formation, a surface treatment such as a plasma treatment may be carried out so as to control the resistivity. The film thickness of the transparent electrode 2 is determined based upon a required sheet resistance value and visible light transmittance. Moreover, a conductive resin such as poly-aniline may also be used. Here, by making the opposing electrode 7 transparent or translucent, light emission may be taken out from both of the surfaces.

Next, the dielectric layers 3 and 6 are described. The dielectric layers 3 and 6 preferably have a high dielectric constant and a high electric insulating property. In the case of an inorganic EL element of an alternate current driving type, an electric current flowing through the phosphor layer which contributes to light emission, is virtually in proportion to the capacity of the dielectric layer. Therefore, by increasing the capacity of the dielectric layer, the driving voltage can be lowered and high brightness can be achieved. With respect to the dielectric material, an oxide and a nitride, or a composite material of these may be used. Preferable examples of these include SiO₂, Si₃N₄, PbO, PbO₂, Al₂O₃, TiO₂, ZrO₂, HfO₂, Nb₂O₅, Ta₂O₅, Li₂O, CaO, SrO, BaO, Y₂O₃, BaTiO₃, BaTa₂O₆, LiNbO₃, SrTiO₃, PbTiO₃, PbZrO₃, Pb(Ti, Zr)O₃ and PbNb₂O₆. It is noted that the dielectric material is not limited in the above-mentioned materials. Here, two or more kinds of these may be used in combination, or may be stacked as different layers, or may be mixed. Moreover, in order to take out light from the phosphor layer 4, the first dielectric layer 3 preferably has a transmittance of 80% or more, in particular, 90% or more, within a visible light range.

With respect to the film-forming method for the dielectric layers 3 and 6, methods such as a sputtering method, an EB vapor deposition method, a resistance heating vapor deposition method, a CVD method and a sol-gel method may be used. The film thickness of the dielectric layers 3 and 6 is preferably in a range from 0.01 to 1 μm, preferably from 0.1 μm to 0.5 μm. Moreover, after the film-forming process, the dielectric layers 3 and 6 may be subjected to a heating treatment in a single gas or mixed gas atmosphere of air, N₂, He, Ar or the like, or in vacuum. Thus, by improving, for example, the crystallizing property of the dielectric layer, higher brightness can be achieved. The temperature of the heating treatment is determined in consideration of influences to the material for the phosphor layer, the substrate and the like, within a temperature range under the melting point of the material for the dielectric layer.

The phosphor layer 4 is described. With respect to the phosphor layer 4, a known phosphor material such as a compound belonging to any of Groups 12 to 16, typically represented by the above-mentioned ZnS doped with Mn, may be used. It is noted that the phosphor layer 4 is not limited in the above-mentioned materials.

With respect to the film-forming method of the phosphor layer 4, methods such as a sputtering method, an EB vapor deposition method, a resistance heating vapor deposition method and a CVD method may be used. When the film thickness of the phosphor layer 4 is too thin, the light-emitting efficiency is lowered, and when the film thickness of the phosphor layer 4 is too thick, the driving voltage is raised. Preferably, the phosphor layer 4 has a thickness ranging from 0.1 μm to 2 μm. It is noted that the film thickness of the phosphor layer 4 is not limited in the above-mentioned range.

Moreover, after the film formation, the phosphor layer 4 may be subjected to a heating treatment. Although it depends on the material for the phosphor layer, the temperature of the heating treatment is preferably 400° C. or more, within a range under the firing temperature of the dielectric layers 3 and 6. With respect to the atmosphere at the time of the heating treatment, a single gas or mixed gas atmosphere of air, N₂, He, Ar and the like can be used.

The photoelectric conversion layer 5 is explained. With respect to the photoelectric conversion layer 5, a photoelectric converting material which exhibits a so-called photoconductive effect, that is, a property in which upon absorption of light, electron-hole pairs are excited to cause an increased conductivity, may be used. With respect to the photoelectric conversion material that exhibits the photoconductive effect, there are two kinds of materials, that is, an intrinsic photoconductive material which absorbs light having an energy greater than a band gap of its own to excite electron-hole pairs through interband transition and an extrinsic photoconductive material which uses a material doped with impurities and excites carriers from its comparatively shallow impurity level. With respect to the photoelectric conversion material, in terms of practical use, photosensitive materials to be used in the electro-photographic process and various materials to be used for image pickup tubes may be used. Preferable examples of the photoelectric conversion materials include inorganic materials including amorphous calcogenide-based materials such as a-Se, a-Se—Te, a-Se—As and a-As₂Se₃, amorphous tetrahedral-based materials such as a-Si, a-SiC, a-SiO and a-SiON, and semiconductor-based materials of compounds belonging to any of Group 12 to Group 16, such as ZnO, CdS, CdSe and PbS, or organic materials including condensed polycyclic quinone-based materials such as perylene, azo pigments, indigo pigments, phthalocyanine pigments, squarylium dye, azulenium dye, thiapyrilium dye and cyanine dye, or composite materials of these. It is noted that the photoelectric conversion layer 5 is not limited in the above-mentioned materials. Moreover, the main photoelectric conversion material of these may be doped with a pigment and the like so as to improve sensitization. Furthermore, a stacking structure of a plurality of photoelectric conversion materials may be used. A thin film in which each of these photoelectric conversion materials is resin-dispersed may be used.

With respect to the film-forming method for the photo-electric conversion layer 5, although it depends on the material to be used, a sputtering method, an EB vapor deposition method, a resistance heating vapor deposition method, a CVD method and the like may be used. The photoelectric conversion layer 5 preferably has a film thickness ranging from 0.01 μm to 10 μm. It is noted that the film thickness of the photoelectric conversion layer 5 is not limited in the above-mentioned range.

In the following description, functions of the photoelectric conversion layer 5 will be discussed. Upon applying an electric field as high as 10⁶ V/cm to the inorganic EL element 10, electrons are injected into the phosphor layer 4 by Poole-Frenkel effect or tunnel effect to collide with and excite luminescent centers of the fluorescent material, and light is emitted when they are relaxed. When this light emission reaches the photoelectric conversion material inside the photoelectric conversion layer 5, photo-excited electron-hole pairs are generated. In the case of a small external electric field, these electron-hole pairs are bound by mutual coulomb fields, and cannot move freely to be soon recombined with each other; however, by the function of the high electric field applied to the inorganic EL element 10, they are separated to form a so-called photocurrent. Some of the separated electrons are again injected into the phosphor layer 4 and caused to collide with and excite the fluorescent material, thereby contributing to light emission. By the functions as described above, it is possible to obtain a light-emitting element with high brightness and high light-emitting efficiency.

The EL element 10 has a structure having a single phosphor layer 4 and a single photoelectric conversion layer 5 respectively formed. The EL element 10 may have one or more phosphor layers and one or more photoelectric conversion layer respectively stacked. For example, The EL element 10 may have two phosphor layers and a photoelectric conversion layer sandwiched between the two phosphor layers.

The opposing electrode 7 is described. With respect to the opposing electrode 7, those materials having a low electric resistance and good adhesion to the dielectric layer 6 are preferably used, and a known metal electrode typically represented by Al may be used. In order to improve the external light contrast, a blackened electrode material such as carbon, MnO₂ and TiO₂ may be used. With respect to the method of forming the opposing electrode 7, known film-forming methods such as a resistance heating vapor deposition method, a sputtering method and a screen printing method may be used.

### Second Embodiment

Referring to FIG. 2, a display device according to the second embodiment of the present invention will be described in the following. FIG. 2 is a schematic plan view showing a passive matrix display device configured by x-electrodes 21 and y-electrodes 22 that are orthogonal to each other, in the display device 20. The display device 20 is provided with a light-emitting element array in which a plurality of EL elements according to the first embodiment are arranged two-dimensionally. Moreover, a plurality of x-electrodes 21 extending in parallel with a first direction parallel to the surface of the light-emitting element array and a plurality of y-electrodes 22 extending in parallel with a second direction orthogonal to the first direction are provided, and these elements respectively correspond to the transparent electrode and the opposing electrode of the EL element according to the aforementioned first embodiment. Moreover, this display device 20 drives one EL element by applying an external alternate current voltage between a pair of the transparent electrode and opposing electrode so that light is taken out from the transparent electrode. According to the display device 20, a photoelectric conversion layer 5 is provided with the EL element of each pixel. Thus, it is possible to obtain a display device having high brightness and high light-emitting efficiency.

Moreover, in the case of a color display device, the phosphor layer 4 may be formed by respective fluorescent materials having respective colors of R (red), G (green) and B (blue). Alternatively, phosphor layers of respective RGB colors may be stacked. Moreover, in the case of a color display device of another example, after forming a display device having a phosphor layer of a single color or phosphor layers of two colors, RGB colors may be displayed by using color filters and/or color conversion filters.

### Third Embodiment

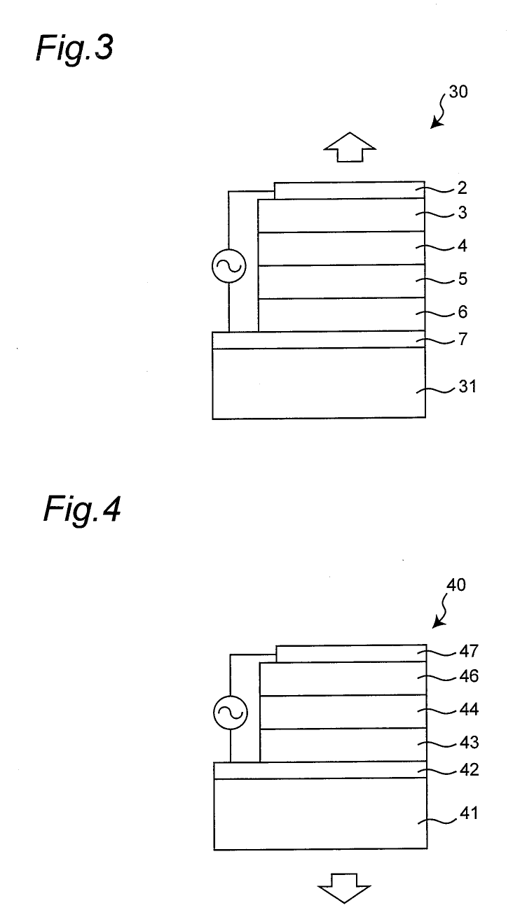

Referring to FIG. 3, a description will be made on the EL element according to a third embodiment of the present invention. FIG. 3 is a cross-sectional view that is perpendicular to the light-emitting surface of an EL element 30. This EL element 30 differs from the EL element 10 according to the first embodiment in that the electrodes and layers are formed on a substrate 31 so that light emission is taken out from the transparent electrode 2. More specifically, this EL element 30 differs from the EL element 10 of the first embodiment in that an opposing electrode 7, a second dielectric layer 6, a photoelectric conversion layer 5, a phosphor layer 4, a first dielectric layer 3 and a transparent electrode 2 are successively stacked on a substrate 31.

In the following description, respective constituent members of the EL element 30 will be discussed in detail. Here, with respect to the members having virtually the same structures as those of the EL element 10 according to the first embodiment, the detailed description thereof is omitted.

With respect to the substrate 31, any material may be used as long as it can support the respective layers formed thereon and have a high electric insulating property. Preferably, it is good in adhesion to the opposing electrode 7.

For example, a glass substrate and a resin substrate such as Corning 1737, that are the same as those of the transparent substrate 1 may be used as the substrate 31. Moreover, the substrate 31 can be selected from a metal substrate, a ceramic substrate, a silicon wafer or the like, each having an insulating layer on its surface.

The EL element according to the present invention is effectively applicable to display devices, in particular, as a display device for a television.

Each of the above-mentioned embodiments only shows one example of the arrangement of the present invention, and the arrangement of the present invention is not limited by the above-mentioned arrangements according to the above described embodiments.

1. An electroluminescent element comprising:
a first electrode;
a first dielectric layer formed on the first electrode;
a second dielectric layer formed to oppose the first dielectric layer;
a second electrode formed on the second dielectric layer;
a phosphor layer sandwiched between the first dielectric layer and the second dielectric layer; and
a photoelectric conversion layer which generates electron-hole pairs by light from the phosphor layer, wherein the photoelectric conversion layer is sandwiched between the first dielectric layer and the second dielectric layer,
wherein at least one of the first electrode and the second electrode is transparent or translucent.

2. The electroluminescent element according to claim 1, wherein the photoelectric conversion layer mainly includes at least one material of an amorphous calcogenide-based material, an amorphous tetrahedral-based material, and a semiconductor material of a compound belonging to any of Groups 12 to 16.

3. The electroluminescent element according to claim 1, wherein the photoelectric conversion layer mainly includes at least one material of a condensed polycyclic quinone-based material, an azo-based material, an indigo-based material, a phthalocyanine-based material, a naphthalocyanine-based material, a squarylium-based material, an azulenium-based material, a thiapyrilium-based material, and a cyanine-based material.

4. The electroluminescent element according to claim 1, wherein the phosphor layer is an inorganic fluorescent thin film.

5. A display device comprising:
a light-emitting element array in which a plurality of the electroluminescent elements according to claim 1 are two-dimensionally arranged;
a plurality of x-electrodes extending in parallel with each other in a first direction parallel with a light-emitting surface of the light-emitting element array; and
a plurality of y-electrodes extending in parallel with a second direction that is orthogonal to the first direction and is parallel with the light-emitting surface of the light-emitting element array.

6. An electroluminescent element comprising:
a first electrode that is transparent or translucent;
a first dielectric layer formed on the first electrode;
a phosphor layer formed on the first dielectric layer;
a photoelectric conversion layer formed on the phosphor layer, wherein the photoelectric conversion layer generates electron-hole pairs by light from the phosphor layer;
a second dielectric layer formed on the photoelectric conversion layer; and
a second electrode formed on the second dielectric layer.

7. The electroluminescent element according to claim 6, wherein the photoelectric conversion layer mainly includes at least one material of an amorphous calcogenide-based material, an amorphous tetrahedral-based material, and a semiconductor material of a compound belonging to any of Groups 12 to 16.

8. The electroluminescent element according to claim 6, wherein the photoelectric conversion layer mainly includes at least one material of a condensed polycyclic quinone-based material, an azo-based material, an indigo-based material, a phthalocyanine-based material, a naphthalocyanine-based material, a squarylium-based material, an azulenium-based material, a thiapyrilium-based material, and a cyanine-based material.

9. The electroluminescent element according to claim 6, wherein the phosphor layer is an inorganic fluorescent thin film.
